(19) United States
(12) Patent Application Publication
(10) Pub. No.: US 2026/0098144 A1
(43) Pub. Date: Apr. 9, 2026

(54) RESIN COMPOSITION, FILM WITH RESIN, PREPREG, SHEET OF METAL FOIL WITH RESIN, METAL-CLAD LAMINATE, AND PRINTED WIRING BOARD

(71) Applicant: Panasonic Intellectual Property Management Co., Ltd., Osaka (JP)

(72) Inventors: Akihiro YAMAUCHI, Osaka (JP); Yasunari TOMITA, Osaka (JP); Nobuo SHIBATA, Toyama (JP); Eiichiro SAITO, Osaka (JP)

(73) Assignee: Panasonic Intellectual Property Management Co., Ltd., Osaka (JP)

(21) Appl. No.: 19/144,189

(22) PCT Filed: Dec. 20, 2023
(86) PCT No.: PCT/JP2023/045737

§ 371 Date: Jun. 27, 2025

(30) Foreign Application Priority Data
Dec. 27, 2022 (JP) 2022-210790

(51) Int. Cl. C08K 13/02; B32B 15/092; B32B 27/20; B32B 27/38; C08J 5/24; C08K 3/22; C08K 3/26; C08K 3/28; C08K 5/24; C09K 5/14; H05K 1/03

(52) U.S. Cl. CPC C08K 13/02; B32B 15/092; B32B 27/20; B32B 27/38; C08J 5/249; C09K 5/14; H05K 1/0366; H05K 1/0373; B32B 2250/02; B32B 2264/1023; B32B 2264/303; B32B 2307/302; B32B 2457/08; C08J 2363/00; C08K 2003/222; C08K 2003/2227; C08K 2003/267; C08K 2003/282; C08K 5/24; C08K 2201/001; C08K 2201/005; C08K 2201/014; H05K 2201/0209

(57) ABSTRACT

A resin composition contains: an epoxy resin (A); an inorganic filler (B) having a thermal conductivity equal to or greater than 10 W/m·K; and at least one selected from the group consisting of a heavy metal deactivator (C) and an ion scavenger (D). The inorganic filler (B) has a volume-based cumulative 99% particle size equal to or less than 50 μm as measured by a laser diffraction particle size distribution analysis method. The content of the inorganic filler (B) is equal to or greater than 84% by mass and equal to or less than 97% by mass with respect to the resin composition.

### TECHNICAL FIELD

The present disclosure generally relates to a resin composition, a film with resin, a prepreg, a sheet of metal foil with resin, a metal-clad laminate, and a printed wiring board. More particularly, the present disclosure relates to a resin composition containing an epoxy resin, a film with resin, a prepreg, a sheet of metal foil with resin, a metal-clad laminate, and a printed wiring board.

### BACKGROUND ART

Patent Document 1 discloses a flame-retardant adhesive composition containing a non-halogen epoxy resin (A), a specific acrylic resin and/or acrylonitrile-butadiene rubber (B), a curing agent (C), a specific phosphinate and/or diphosphinate (E), and an ion scavenger and/or a heavy metal deactivator (F). Patent Document 2 discloses an epoxy resin composition containing an epoxy resin (a), a curing agent (b), a specific polyamide-poly(butadiene-acrylonitrile) copolymer (c), an ion scavenger (d), and a heavy metal deactivator (e). They say that the techniques of Patent Documents 1 and 2 make the migration resistance of a cured product of the resin composition improvable, thus improving insulation reliability even under high temperature and high humidity conditions as in a printed wiring board which uses the cured product as a material for its insulating layer.

Recently, the number of semiconductor devices integrated per unit area on a board has been increasing, and their feature size has been further decreased, more and more significantly, thus requiring printed wiring boards used to mount those devices to improve various characteristics of theirs increasingly significantly. In particular, as the functionalities of semiconductor devices have been enhanced, the quantity of heat generated by those devices has been on the rise. In addition, such a significant increase in the number of devices integrated per unit area and a tremendous increase in the density of devices mounted on the board make the heat generated easily accumulated inside the housing. Under the circumstances such as these, printed wiring boards are increasingly required to use improved heat dissipation techniques. Consequently, there has been an increasing demand for improving the thermal conductivity of a cured product of a resin composition that forms an insulating layer of printed wiring boards.

Nevertheless, neither Patent Document 1 nor Patent Document 2 carefully looks into an inorganic filler contained in the resin composition or provides any effective measure for improving the thermal conductivity of a cured product of the resin composition.

### CITATION LIST

### Patent Literature

Patent Document 1: JP 2008-111102A
Patent Document 2: JP 2003-026773 A

### SUMMARY OF INVENTION

An object of the present disclosure is to provide a resin composition which may be used to form a cured product having both high thermal conductivity and excellent insulation reliability and also provide a film with resin, a prepreg, a sheet of metal foil with resin, a metal-clad laminate, and a printed wiring board.

A resin composition according to an aspect of the present disclosure contains: an epoxy resin (A): an inorganic filler (B) having a thermal conductivity equal to or greater than 10 W/m·K; and at least one selected from the group consisting of a heavy metal deactivator (C) and an ion scavenger (D). The inorganic filler (B) has a volume-based cumulative 99% particle size equal to or less than 50 μm as measured by a laser diffraction particle size distribution analysis method. The content of the inorganic filler (B) is equal to or greater than 84% by mass and equal to or less than 97% by mass with respect to the resin composition.

A film with resin according to another aspect of the present disclosure includes: a resin layer including either the resin composition described above or a semi-cured product of the resin composition; and a supporting film.

A prepreg according to still another aspect of the present disclosure includes: a resin layer including either the resin composition described above or a semi-cured product of the resin composition; and a fibrous base member.

A sheet of metal foil with resin according to yet another aspect of the present disclosure includes: a resin layer including either the resin composition described above or a semi-cured product of the resin composition; and a sheet of metal foil.

A metal-clad laminate according to yet another aspect of the present disclosure includes: an insulating layer including either a cured product of the resin composition described above or a cured product of the prepreg described above; and a metal layer.

A printed wiring board according to yet another aspect of the present disclosure includes: an insulating layer including either a cured product of the resin composition described above or a cured product of the prepreg described above; and wiring.

### BRIEF DESCRIPTION OF DRAWINGS

FIG. 1A is a schematic cross-sectional view illustrating a film with resin (and with no protective film) according to an exemplary embodiment of the present disclosure; and FIG. 1B is a schematic cross-sectional view illustrating a film with resin (and with a protective film) according to the exemplary embodiment of the present disclosure;

FIG. 2 is a schematic cross-sectional view illustrating a prepreg according to the exemplary embodiment of the present disclosure:

FIG. 3 is a schematic cross-sectional view illustrating a sheet of metal foil with resin according to the exemplary embodiment of the present disclosure:

FIG. 4A is a schematic cross-sectional view illustrating a metal-clad laminate (including a cured product of a resin composition) according to the exemplary embodiment of the present disclosure; and FIG. 4B is a schematic cross-sectional view illustrating a metal-clad laminate (including a cured product of a prepreg) according to the exemplary embodiment of the present disclosure:

FIG. 5A is a schematic cross-sectional view illustrating a printed wiring board (including a cured product of a resin composition) according to the exemplary embodiment of the present disclosure; and FIG. 5B is a schematic cross-sectional view illustrating a printed wiring board (including a cured product of a prepreg) according to the exemplary embodiment of the present disclosure;

FIG. 6 is a schematic cross-sectional view illustrating a board for evaluating long-term reliability for use in an example of the present disclosure; and

FIG. 7 is a schematic plan view illustrating a part formed on the board for evaluating long-term reliability.

### DESCRIPTION OF EMBODIMENTS

### 1. Overview

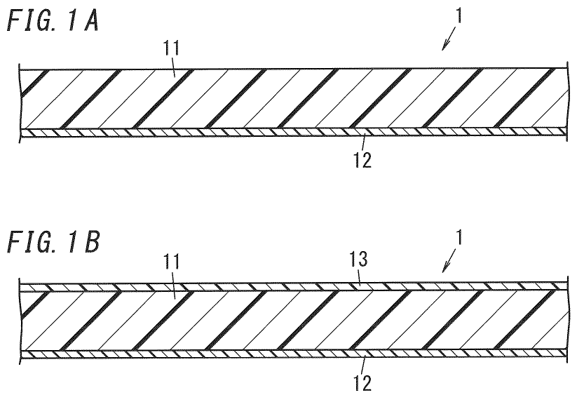

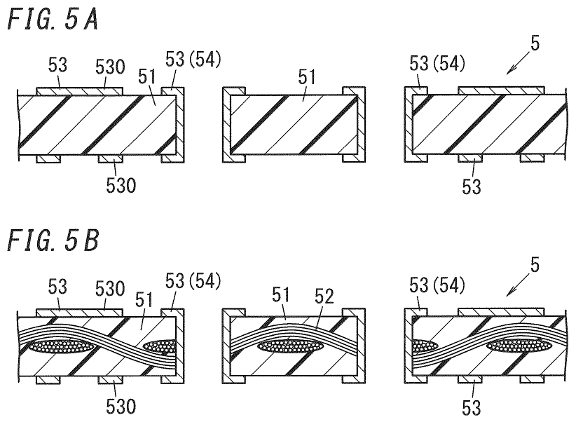

A resin composition according to an exemplary embodiment is used mainly as a material for a printed wiring board 5 (refer to FIG. 5). Examples of materials for the printed wiring board 5 include, without limitation, a film 1 with resin, a prepreg 2, a sheet of metal foil 3 with resin, and a metal-clad laminate 4 (refer to FIGS. 1-4).

A resin composition according to this embodiment contains an epoxy resin (A), an inorganic filler (B), and at least one selected from the group consisting of a heavy metal deactivator (C) and an ion scavenger (D). The inorganic filler (B) has a thermal conductivity equal to or greater than 10 W/m·K. The inorganic filler (B) has a volume-based cumulative 99% particle size equal to or less than 50 μm as measured by a laser diffraction particle size distribution analysis method. The content of the inorganic filler (B) is equal to or greater than 84% by mass and equal to or less than 97% by mass with respect to the resin composition.

A resin composition according to this embodiment may be used to form a cured product exhibiting not only high thermal conductivity but also excellent insulation reliability as well.

The present inventors discovered that the problems described above would be overcome by adding a heavy metal deactivator and/or an ion scavenger to a resin composition containing an epoxy resin, using an inorganic filler having a thermal conductivity and a particle size distribution, each falling within a particular range, and setting the content of the inorganic filler at a value falling within a particular range, thereby conceiving the concept of the present disclosure.

The resin composition according to this embodiment includes not only the epoxy resin (A) but also at least one of the heavy metal deactivator (C) or the ion scavenger (D), and therefore, may exhibit migration resistance high enough to improve the insulation reliability. In addition, the resin composition according to this embodiment uses, as the inorganic filler (B), an inorganic filler having not only a relatively high thermal conductivity equal to or greater than a specific value but also a particle size distribution with a volume-based cumulative 99% particle size equal to or less than a specific value with the content of the inorganic filler set at a value falling within a particular range. This may improve the thermal conductivity while maintaining sufficient insulation reliability. The reason why the resin composition with such features according to this embodiment achieves these advantages is not quite clear at this time. In any case, these advantages of improving the thermal conductivity while maintaining sufficient insulation reliability would be achieved by, for example, setting the cumulative 99% particle size at a predetermined value or less to reduce the percentage of relatively large particles to a certain value or less and by setting the content of the inorganic filler (B) at a value falling within the particular range to increase the fillability of the inorganic filler (B) in the resin composition.

As can be seen, the present disclosure allows for providing a cured product which exhibits not only high thermal conductivity but also excellent insulation reliability as well.

### 2. Details

### <Resin Composition>

The resin composition contains an epoxy resin (A), an inorganic filler (B), and at least one selected from the group consisting of a heavy metal deactivator (C) and an ion scavenger (D). Optionally, the resin composition may further contain a curing agent (E), a curing catalyst (F), and/or a flame retardant (G). The resin composition may further contain additional components (H) as well. Note that the phrase “X and/or Y” as used herein means at least one of X or Y.

The resin composition has thermosetting properties. When heated, the resin composition turns into a semi-cured product. When further heated, the semi-cured product of the resin composition turns into a cured product. The semi-cured product is a substance in a semi-cured state, and the cured product is a substance in a cured state (insoluble and non-meltable state). As used herein, the “semi-cured state” refers to a state in an intermediate stage (stage B) of the curing reaction. The intermediate stage is a stage between a varnished stage (stage A) and a cured stage (stage C).

Next, respective constituent components of the resin composition will be described.

### <<Epoxy Resin>>

The epoxy resin (A) is a prepolymer and is a resin having at least two epoxy groups in its molecule. The epoxy resin (A) will be hereinafter sometimes referred to as an “epoxy compound.” Generally speaking, the term “resin” refers to two different types of resins, namely, a resin as a material which has not been cross-linked yet and a resin as a cross-linked product (final product). As used herein, the “resin” basically refers to the former type of resin.

Examples of the epoxy resin (A) include, without limitation, naphthalene epoxy resins, cresol-novolac epoxy resins, bisphenol A epoxy resins, bisphenol F epoxy resins, bisphenol S epoxy resins, trisphenol-methane epoxy resins, phenol-novolac epoxy resins, alkyl phenol-novolac epoxy resins, aralkyl epoxy resins, biphenol epoxy resins, dicyclopentadiene epoxy resins, epoxidized products of condensate of phenols and aromatic aldehyde having a phenolic hydroxyl group, triglycidyl isocyanurate, and alicyclic epoxy resins. The epoxy resin (A) may include at least one epoxy resin selected from this group. The epoxy resin (A) preferably includes a trisphenol-methane epoxy resin.

The content of the epoxy resin (A) with respect to the resin composition is preferably equal to or greater than 1% by mass and equal to or less than 10% by mass, and more preferably equal to or greater than 2% by mass and equal to or less than 5% by mass.

### <<Inorganic Filler>>

As used herein, the “inorganic filler” refers to a filler made of an inorganic material. It is important that the inorganic filler (B) has the following three features (1) to (3).

(1) The inorganic filler (B) should have a thermal conductivity equal to or greater than 10 W/m·K. If the thermal conductivity of the inorganic filler (B) were less than 10 W/m·K, then the thermal conductivity of the cured product of the resin composition would decrease. The upper limit of the thermal conductivity of the inorganic filler (B) is not limited to any particular value but may be, for example, equal to or less than 300 W/m·K.

(2) The inorganic filler (B) should have a volume-based cumulative 99% particle size (D99) equal to or less than 50 μm. As used herein, the “volume-based cumulative 99% particle size” refers to a particle size, of which the cumulative value calculated from the smallest particle size in a volume-based particle size distribution is 99%. D99 herein refers to a value measured by the laser diffraction particle size distribution analysis method. As the laser diffraction particle size distribution analyzer, SALD-2300 manufactured by Shimadzu Corporation may be used, for example. If D99 of the inorganic filler (B) were greater than 50 μm, then the insulation reliability of the cured product of the resin composition would decrease. D99 is preferably equal to or less than 45 μm and more preferably equal to or less than 40 μm. The lower limit of D99 is not limited to any particular value but may be, for example, equal to or greater than 10 μm and is preferably equal to or greater than 15 μm.

(3) The content of the inorganic filler (B) should be equal to or greater than 84% by mass and equal to or less than 97% by mass with respect to the resin composition. If the content were less than 84% by mass, then the proportion of the inorganic filler (B) would be too small to avoid causing a decline in the thermal conductivity of the cured product of the resin composition. If the content were greater than 97% by mass, then the fillability of the inorganic filler (B) in the resin composition would decrease so significantly as to cause a decline in the thermal conductivity of the cured product of the resin composition. The content of the inorganic filler (B) is preferably equal to or greater than 85% by mass and equal to or less than 96% by mass, more preferably equal to or greater than 86% by mass and equal to or less than 95% by mass, and even more preferably equal to or greater than 87% by mass and equal to or less than 94% by mass, with respect to the resin composition.

The volume-based cumulative 50% particle size (D50) of the inorganic filler (B) is preferably equal to or less than 30 μm, more preferably equal to or less than 20 μm, and even more preferably equal to or less than 15 μm.

The inorganic filler (B) is not limited to any particular filler as long as the thermal conductivity thereof is equal to or greater than the above-described lower limit value, but may be, for example, an aluminum oxide filler (alumina filler), a magnesium oxide filler, an anhydrous magnesium carbonate filler, or an aluminum nitride filler. These fillers are preferred because all of these fillers have a high thermal conductivity and are easily available.

The inorganic filler (B) may be used either by itself or in combination with at least one more inorganic filler, whichever is appropriate. If the inorganic filler (B) is a mixture of two or more inorganic fillers, then the thermal conductivity, D99, and content of the inorganic filler (B) described above refer to the values about the mixture.

The inorganic filler (B) preferably has at least two peaks in the volume-based particle size distribution measured by the laser diffraction analysis method. The at least two peaks include a first peak and a second peak. This allows for further increasing the fillability of the inorganic filler (B) in the resin composition. The inorganic filler (B) may have two peaks or three or more peaks, whichever is appropriate. Also, in this case, the first peak is preferably located at a point greater than 1 μm and equal to or less than 30 μm. The second peak is preferably located at a point equal to or greater than 0.1 μm and equal to or less than 1 μm. Using an inorganic filler (B) having two peaks falling within such a particle size range allows for further increasing the fillability of the inorganic filler (B) in the resin composition, and eventually, further improving the thermal conductivity of the cured product of the resin composition.

The inorganic filler (B) preferably includes at least two inorganic fillers including a first inorganic filler (B1) marking the first peak and a second inorganic filler (B2) marking the second peak. Using such an inorganic filler (B) including at least two inorganic fillers having mutually different peak points in the particle size distribution allows for further increasing the fillability of the inorganic filler (B) in the resin composition and eventually improving the thermal conductivity of the cured product of the resin composition. The inorganic filler (B) may include two or more inorganic fillers or even three or more inorganic fillers.

The first inorganic filler (B1) preferably includes at least one filler selected from the group consisting of an aluminum oxide filler, a magnesium oxide filler, an anhydrous magnesium carbonate filler, and an aluminum nitride filler. Using one of these fillers with relatively high thermal conductivity as the first inorganic filler (B1) having the larger particle size among the at least two types of inorganic fillers (B) enables the thermal conductivity of the cured product of the resin composition to be further improved.

Examples of shapes of the first inorganic filler (B1) include spherical, round, chain-like, dissimilar, and indefinite shapes.

The second inorganic filler (B2) preferably has either a spherical shape or a round shape. Using a filler with such a shape as the second inorganic filler (B2) having the smaller particle size in the inorganic filler (B) allows the resin composition to have an even higher fillability of the inorganic filler (B) and thereby enables the thermal conductivity of the cured product to be further improved.

The (B1)/(B2) ratio by volume of the first inorganic filler (B1) to the second inorganic filler (B2) is preferably equal to or greater than 40/60 and equal to or less than 70/30. Setting the (B1)/(B2) ratio by volume at a value falling within this range allows the resin composition to have an even higher fillability of the inorganic filler (B) and thereby enables the thermal conductivity of the cured product of the resin composition to be further improved.

The inorganic filler (B) for use to prepare the resin composition preferably has a low content of impurity ions. Using an inorganic filler (B) including a lot of impurity ions would cause a decline in the insulation reliability of the cured product of the resin composition. Among other things, Cl⁻, SO₄²⁻, PO₄³⁻, NO₂⁻, NO₃⁻, and NH₄⁺ ions would accelerate the elution of copper during migration, thus causing a significant decline in insulation reliability.

The content of impurity ions in the inorganic filler (B) may be estimated specifically by measuring not only the electrical conductivity of extracted water, obtained from the inorganic filler (B) and ultrapure water by a predetermined method, but also the concentration of impurity ions in the extracted water. The electrical conductivity of the extracted water is preferably equal to or less than 500 μS/cm, more preferably equal to or less than 300 μS/cm, and even more preferably equal to or less than 100 μS/cm. The lower limit of the electrical conductivity of the extracted water may be, for example, equal to or greater than 1 μS/cm. Furthermore, the concentration of each of Cl⁻, SO₄²⁻, PO₄³⁻, NO₂⁻, NO₃⁻, and NH₄⁺ ions in the extracted water is preferably equal to or less than 20 ppm, more preferably equal to or less than 10 ppm, and even more preferably equal to or less than 5 ppm. The lower limit of the concentration of each of these impurity ions may be, for example, equal to or greater than 2 ppm, which is the detection limit. Setting the electrical conductivity of the extracted water obtained from the inorganic filler (B) and the respective concentrations of the impurity ions in the extracted water at respective values falling within these ranges enables the insulation reliability of the cured product of the resin composition to be further improved.

The electrical conductivity of this extracted water and the respective concentrations of these ions may be measured in the following manner, for example. First, a sample of the inorganic filler (B) is ultrasonically cleaned with ultrapure water for 20 minutes to turn the sample into a powder of 100 mesh under and 200 mesh up. Then, the powdered sample is washed with ultrapure water and isopropanol and then dried. Next, 15 g of the dried sample thus obtained and 7.5 g of ultrapure water are charged into a container such as a pressure cooker container and mixed. The pressure cooker container is a double-layered container of which the inner part is made of Teflon® and the outer part is made of stainless steel. As used herein, the “ultrapure water” refers to water with a high purity that contains a very small amount of impurities and has an electrical conductivity equal to or less than 1 μS/cm at 25° C. It is preferable to use ultrapure water with an electrical conductivity equal to or less than 0.1 μS/cm. Next, the container is heated at 125° C. for 20 hours. After the container has been heated, the contents of the container are removed and extracted water (aqueous layer) is obtained by centrifugation, for example. The electrical conductivity of the extracted water thus obtained may be measured, for example, with a conductivity meter, for example. Furthermore, the concentrations of Cl⁻, SO₄²⁻, PO₄³⁻, NO₂⁻, NO₃⁻, and NH₄⁺ ions in the extracted water may be measured, for example, by ion chromatography.

### <Other Inorganic Fillers>

The resin composition may contain, in addition to the inorganic filler (B), other inorganic fillers having a thermal conductivity less than the above-mentioned value, as long as the content of the inorganic filler (B) falls within the above-mentioned range. Examples of other inorganic fillers include a molybdic acid compound filler and a silica filler.

### <<Heavy Metal Deactivator>>

The heavy metal deactivator (C) is a substance which may form a chemical bond such as a chelate bond with a heavy metal atom or an ion. The heavy metal deactivator (C) may reduce the reduction and precipitation of metals by trapping metal ions such as copper ions eluted during migration, thereby allowing for improving migration resistance. The heavy metal deactivator (C) is also sometimes called a “copper damage inhibitor.” The heavy metal deactivator (C) may be used either by itself or as a mixture of two or more types of heavy metal deactivators.

Examples of heavy metal deactivators (C) include hydrazide-based nitrogen compounds, triazine-based nitrogen compounds, and triazole-based nitrogen compounds.

Examples of hydrazide-based nitrogen compounds include N,N′-diformylhydrazine, N,N′-diacetylhydrazine, N,N′-di(propionyl) hydrazine, N,N′-butyrylhydrazine, N-formyl-N′-acetylhydrazine, N,N′-dibenzoylhydrazine, N,N′-ditoluoylhydrazine, N,N′-disalicyloylhydrazine, N-formyl-N′-salicyloylhydrazine, N-formyl-N′-butyl-substituted salicyloyl hydrazine, N-acetyl-N′-salicyloyl hydrazine, N,N′-bis [3-(3,5-di-t-butyl-4-hydroxyphenyl) propionyl]hydrazine, oxalic acid-di-(N′-salicyloyl) hydrazine, adipic acid-di-(N′-salicyloyl) hydrazine, and dodecane dioyl-di-(N′-salicyloyl) hydrazine. Commercially available hydrazide-based nitrogen compounds include, for example, ADEKA STAB CDA-6 and CDA-10 (manufactured by ADEKA Corporation).

Examples of triazine-based nitrogen compounds include 2,4,6-triamino-1,3,5-triazine. Commercially available triazine-based nitrogen compounds include, for example, ADEKA STAB ZS-27 (manufactured by ADEKA Corporation).

Examples of triazole-based nitrogen compounds include 3-amino-1,2,4-triazole, 3-amino-1,2,4-triazole-carboxylic acid, 3-amino-5-methyl-1,2,4-triazole, 3-amino-5-heptyl-1,2,4 triazole; and acid amide derivatives of amino-group-containing triazole compounds such as 3-(N-salicyloyl)amino-1,2,4-triazole, 3-(N-salicyloyl)amino-5-methyl-1,2,4-triazole, and 3-(N-acetyl)amino-1,2,4-triazole-5-carboxylic acid. Commercially available triazole nitrogen compounds include, for example, ADEKA STAB CDA-1 and CDA-1M (manufactured by ADEKA Corporation).

The content of the heavy metal deactivator (C) is preferably equal to or greater than 0.1 parts by mass and equal to or less than 5 parts by mass with respect to the total of resin components in the resin composition, i.e., 100 parts by mass in total of the epoxy resin (A) and the curing agent (E). Setting the content of the heavy metal deactivator (C) at a value falling within this range enables the insulation reliability of the cured product to be further improved. If the content of the heavy metal deactivator (C) were less than 0.1 parts by mass, then the insulation reliability would be improved to an insufficient degree in some cases. On the other hand, if the content of the heavy metal deactivator (C) were greater than 5 parts by mass, then the heavy metal deactivator (C) would be dissolved in the resin components so insufficiently that the insulation reliability would be improved to an insufficient degree in some cases. The content of the heavy metal deactivator (C) is more preferably equal to or greater than 0.3 parts by mass and equal to or less than 4 parts by mass, and even more preferably equal to or greater than 0.5 parts by mass and equal to or less than 2 parts by mass.

### <<Ion Scavenger>>>

The ion scavenger (D) is a substance having an ion trapping ability. The ion scavenger (D) improves migration resistance by trapping anions such as phosphate anions, organic acid anions, and halogen anions, and cations such as alkali metal cations and alkaline earth metal cations and thereby reducing ionic impurities.

Examples of ion scavengers (D) include hydrotalcite-based ion scavengers, bismuth oxide-based ion scavengers, antimony oxide-based ion scavengers, titanium phosphate-based ion scavengers, and zirconium phosphate-based ion scavengers.

Examples of hydrotalcite-based ion scavengers include a substance expressed by the general formula: Mg_{X}Al_{Y} (OH)_{2X+3Y-2Z} (CO₃)_{Z}·mH₂O, where X, Y, and Z are positive numbers satisfying 2X+3Y−2Z≥0, and m is a positive number. Commercially available hydrotalcite-based ion scavengers include IXEPLAS-A1 and IXEPLAS-A3 (both manufactured by Toagosei Co., Ltd.), DHT-4A, and Kyoword KW-2000 (both manufactured by Kyowa Chemical Industry Co., Ltd.).

Examples of bismuth oxide-based ion scavengers include a substance expressed by the general formula: BiO_{X}(OH)_{Y}(NO₃)_{Z}, where X is a positive number falling within the range from 0.9 to 1.1, Y is a positive number falling within the range from 0.6 to 0.8, and Z is a positive number falling within the range from 0.2 to 0.4. Commercially available bismuth oxide-based ion scavengers include, for example, IXE-500 (manufactured by Toagosei Co., Ltd.).

Examples of antimony oxide-based ion scavengers include an ion scavenger containing antimony oxide. Commercially available antimony oxide-based ion scavengers include, for example, IXE-600 (manufactured by Toagosei Co., Ltd.).

Examples of titanium phosphate-based ion scavengers include an ion scavenger containing titanium phosphate. Commercially available titanium phosphate-based ion scavengers include, for example, IXE-400 (manufactured by Toagosei Co., Ltd.).

Examples of zirconium phosphate-based ion scavengers include an ion scavenger containing zirconium phosphate and an ion scavenger containing zirconium polyphosphate. Commercially available zirconium phosphate-based ion scavengers include, for example, IXE-100 (manufactured by Toagosei Co., Ltd.).

The content of the ion scavenger (D) is preferably equal to or greater than 0.1% by mass and equal to or less than 2% by mass with respect to the resin composition. Setting the content of the ion scavenger (D) at a value falling within this range enables the insulation reliability of the cured product to be further improved. If the content of the ion scavenger (D) were less than 0.1% by mass, then the insulation reliability would be improved to an insufficient degree in some cases. On the other hand, if the content of the ion scavenger (D) were greater than 2% by mass, then the ion scavenger (D) would be dispersed in the resin components so non-uniformly that the insulation reliability would be improved to an insufficient degree in some cases. The content of the ion scavenger (D) is more preferably equal to or greater than 0.3% by mass and equal to or less than 1.8% by mass, and even more preferably equal to or greater than 0.5% by mass and equal to or less than 1.5% by mass.

If the heavy metal deactivator (C) and the ion scavenger (D) are used in combination, then the combined content of the heavy metal deactivator (C) and the ion scavenger (D) is preferably equal to or greater than 0.1 parts by mass and equal to or less than 5 parts by mass, more preferably equal to or greater than 0.3 parts by mass and equal to or less than 4 parts by mass, and even more preferably equal to or greater than 0.5 parts by mass and equal to or less than 2 parts by mass, with respect to 100 parts by mass in total of the resin components in the resin composition. The combined content of the heavy metal deactivator (C) and the ion scavenger (D) is preferably equal to or greater than 0.1 parts by mass and equal to or less than 2 parts by mass, more preferably equal to or greater than 0.3 parts by mass and equal to or less than 1.8 parts by mass, and even more preferably equal to or greater than 0.5 parts by mass and equal to or less than 1.5 parts by mass, with respect to the resin composition.

If the heavy metal deactivator (C) and the ion scavenger (D) are used in combination, then the (D)/(C) ratio by mass of the ion scavenger (D) to the heavy metal deactivator (C) is preferably equal to or greater than 0.1 and equal to or less than 100, more preferably equal to or greater than 0.5 and equal to or less than 50, and even more preferably equal to or greater than 0.8 and equal to or less than 20.

### <<Curing Agent>>

The curing agent (E) may be any compound without limitation as long as the curing agent (E) may produce a curing reaction with the epoxy resin (A).

Examples of the curing agent (E) include phenol-based curing agents, acid anhydrides, amines, imidazoles, hydrazides, polymercaptans, and Lewis acid-amine complexes. It is preferable that the curing agent (E) contain a phenol-based curing agent. A phenol-based curing agent has better curing properties than other curing agents, thus allowing the strength of the cured product of the resin composition to be increased.

Examples of phenol-based curing agents include: novolac resins such as a phenol-novolac resin, a cresol-novolac resin, and a naphthol-novolac resin: aralkyl resins such as a phenol-aralkyl resin having either a phenylene skeleton or a biphenylene skeleton, and a naphthol-aralkyl resin having either a phenylene skeleton or a biphenylene skeleton: polyfunctional phenolic resins such as a triphenolmethane resin: dicyclopentadiene phenolic resins such as a dicyclopentadiene phenol-novolac resin and a dicyclopentadiene naphthol-novolac resin: terpene-modified phenolic resins: bisphenol resins such as bisphenol A and bisphenol F; and triazine-modified novolac resins.

The content of the curing agent (E) is preferably equal to or greater than 10 parts by mass and equal to or less than 200 parts by mass, and more preferably equal to or greater than 30 parts by mass and equal to or less than 100 parts by mass, with respect to 100 parts by mass of the epoxy resin (A).

The equivalent of the curing agent (E) to one equivalent of the epoxy resin (A) may be, for example, equal to or greater than 0.6 and equal to or less than 1.4.

The content of the curing agent (E) is preferably equal to or greater than 0.1% by mass and equal to or less than 20% by mass, and more preferably equal to or greater than 1% by mass and equal to or less than 5% by mass, with respect to the resin composition.

### <<Curing Catalyst>>

The curing catalyst (F) is synonymous with a curing accelerator. Examples of the curing catalyst (F) include, without limitation: imidazoles such as 2-ethyl-4-methylimidazole, 2-methylimidazole, and 2-phenyl-4-methylimidazole; amines such as dimethylbenzylamine, triethylenediamine, benzyldimethylamine, and triethanolamine; organic phosphines such as triphenylphosphine, diphenylphosphine, and phenylphosphine; tetra-substituted phosphonium-tetra-substituted borates such as tetraphenylphosphonium ethyltriphenyl borate; and tetraphenyl boron salts such as 2-ethyl-4-methylimidazole tetraphenylborate.

When the resin composition contains a curing catalyst (F), the content of the curing catalyst (F) may be, without limitation, equal to or greater than 0.1 parts by mass and equal to or less than 5 parts by mass with respect to 100 parts by mass in total of the epoxy resin (A) and the curing agent (E).

### <<Flame Retardant>>

Adding a flame retardant (G) to the resin composition allows a cured product of the resin composition to have increased flame retardance.

Examples of the flame retardant (G) include, without limitation, phosphorus-based flame retardants and halogen-based flame retardants.

Examples of the phosphorus-based flame retardants include, without limitation, phosphoric acid esters, phosphazene, bisdiphenylphosphine oxide, and phosphinates. Specific examples of the phosphoric acid esters include a condensed phosphoric acid ester of dixylenyl phosphate. Specific examples of the phosphazene include phenoxyphosphazene. Specific examples of the bisdiphenylphosphine oxide include xylylene bisdiphenylphosphine oxide. Specific examples of the phosphinates include metal phosphinates of aluminum dialkyl phosphinates.

On the other hand, examples of the halogen-based flame retardants include, without limitation, ethylene dipentabromobenzene, ethylene bistetrabromoimide, decabromodiphenyl oxide, and tetradecabromodiphenoxybenzene.

If the resin composition contains any flame retardant (G), the content of the flame retardant (G) may be, for example, equal to or greater than 0.01% by mass and equal to or less than 10% by mass with respect to the resin composition.

### <Other Components>>

The other components (H) are components other than the epoxy resin (A), the inorganic filler (B), the heavy metal deactivator (C), the ion scavenger (D), the curing agent (E), the curing catalyst (F), and the flame retardant (G) described above. Examples of the other components (H) include, without limitation, coupling agents, dispersants, dyes, surfactants, leveling agents, and resins other than the epoxy resin (A). The other component(s) (H) may consist of only one type or include two or more types, whichever is appropriate.

<Film with Resin>

FIGS. 1A and 1B illustrate films 1 with resin according to this embodiment. Each of the films 1 with resin may be used, for example, to form a printed wiring board 5 with multiple levels (by buildup process). The film 1 with resin has the shape of a film as a whole. The film 1 with resin includes a resin layer 11 and a supporting film 12. FIG. 1A illustrates a film 1 with resin and with no protective film 13. FIG. 1B illustrates a film 1 with resin and with a protective film 13 as an additional member. Peeling the protective film 13 off from the film 1 with resin shown in FIG. 1B may turn the film 1 with resin shown in FIG. 1B into the film 1 with resin shown in FIG. 1A.

The resin layer 11 contains the resin composition. The resin composition is a semi-cured product. When heated, the semi-cured product turns into a cured product. In this manner, the resin layer 11 may form an insulating layer.

The thickness of the resin layer 11 is not limited to any particular value but is preferably, equal to or greater than 50 μm and equal to or less than 150 μm, more preferably equal to or greater than 60 μm and equal to or less than 140 μm, and even more preferably equal to or greater than 70 μm and equal to or less than 130 μm. This allows the insulating layer 11 to have higher thermal conductivity and superior insulation reliability.

The supporting film 12 supports the resin layer 11 thereon. Making the supporting film 12 support the resin layer 11 in this way allows the resin layer 11 to be handled more easily.

The supporting film 12 may be an electrically insulating film, for example. Specific examples of the supporting film 12 include a polyethylene terephthalate (PET) film, a polyimide film, a polyester film, a polyparabanic acid film, a polyether ether ketone film, a polyphenylene sulfide film, an aramid film, a polycarbonate film, and a polyarylate film. However, these are only examples and the supporting film 12 does not have to be one of these films.

A release agent layer (not shown) may be provided on the surface, used to support the resin layer 11, of the supporting film 12. The release agent layer allows the supporting film 12 to be peeled off as needed from the resin layer 11.

Although one surface of the resin layer 11 is covered with the supporting film 12 in the example shown in FIG. 1A, the other surface of the resin layer 11 may be covered with a protective film 13 as shown in FIG. 1B. Covering both surfaces of the resin layer 11 in this manner with the supporting film 12 and the protective film 13, respectively, allows the resin layer 11 to be handled even more easily. This also reduces the chances of foreign particles adhering onto the resin layer 11.

The protective film 13 may be an electrically insulating film, for example. Specific examples of the protective film 13 include a polyethylene terephthalate (PET) film, a polyolefin film, a polyester film, and a polymethylpentene film. However, these are only examples and the protective film 13 does not have to be one of these films.

A release agent layer (not shown) or an easily removable adhesive layer (not shown) may be provided on the surface, laid on top of the resin layer 11, of the protective film 13. The release agent layer allows the protective film 13 to be peeled off as needed from the resin layer 11. The easily removable adhesive layer allows the protective film 13 to adhere to the resin layer 11 moderately.

### <Prepreg>

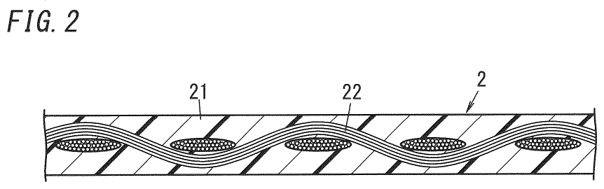

FIG. 2 illustrates a prepreg 2 according to this embodiment. The prepreg 2 has the shape of a sheet. The prepreg 2 includes at least one sheet of fibrous base member 22 and a resin layer 21. The fibrous base member 22 is impregnated with the resin composition. The resin layer 21 contains the resin composition. The resin composition is a semi-cured product.

The fibrous base member 22 is a reinforcing member and is not limited to any particular one. The fibrous base member 22 preferably has, without limitation, a thickness equal to or greater than 10 μm and equal to or less than 300 μm, and more preferably has a thickness equal to or greater than 30 μm and equal to or less than 200 μm.

Specific examples of the fibrous base member 22 include glass cloth, aramid cloth, polyester cloth, glass non-woven fabric, aramid non-woven fabric, polyester non-woven fabric, pulp paper, and linter paper. The types of the glass cloth are preferably #7628, #1501, #2116, #1080, #1078, and #106.

In the manufacturing process of the prepreg 2, the glass cloth is preferably treated with a coupling agent before being impregnated with the resin composition in stage A. Treating the glass cloth with the coupling agent in this manner may increase the degree of adhesion between the glass cloth and the resin composition. Examples of the coupling agent include, without limitation, a silane coupling agent.

A method for manufacturing the prepreg includes the steps of: impregnating the fibrous base member 22 with a resin composition in stage A; and heating the fibrous base member 22 until the resin composition impregnated into the fibrous base member 22 makes a transition to stage B. As used herein, the “stage A” refers to an initial stage on which the resin composition is dissolvable in a certain type of liquid and meltable. That is to say, the resin composition in stage A is a varnish.

<Sheet of Metal Foil with Resin>

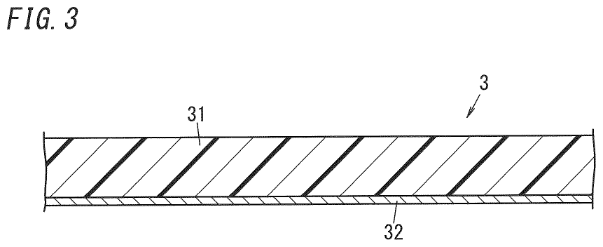

FIG. 3 illustrates a sheet of metal foil 3 with resin according to this embodiment. The sheet of metal foil 3 with resin has the shape of a film as a whole. The sheet of metal foil 3 with resin includes a resin layer 31 and a sheet of metal foil 32. The sheet of metal foil 3 with resin may be used, for example, to form a printed wiring board 5 with multiple levels (by buildup process).

The resin layer 31 contains the resin composition. The resin composition is a semi-cured product. When heated, the semi-cured product may turn into a cured product. In this manner, the resin layer 31 may form an insulating layer.

The thickness of the resin layer 31 is not limited to any particular value but is preferably equal to or greater than 50 μm and equal to or less than 150 μm, more preferably equal to or greater than 60 μm and equal to or less than 140 μm, and even more preferably equal to or greater than 70 μm and equal to or less than 130 μm. This allows even higher thermal conductivity and even superior insulation reliability to be achieved.

The sheet of metal foil 32 is bonded to the resin layer 31. The sheet of metal foil 32 may specifically be, but does not have to be, a sheet of copper foil. The sheet of metal foil 32 may be patterned into wiring 53 by having unnecessary portions thereof etched away by subtractive process, for example.

The thickness of the sheet of metal foil 32 is not limited to any particular value but is preferably equal to or less than 35 μm, and more preferably equal to or less than 18 μm. The sheet of metal foil 32 preferably has a thickness equal to or greater than 5 μm.

Optionally, the sheet of metal foil 32 may be configured as an extremely thin sheet of metal foil (such as an extremely thin sheet of copper foil) of a so-called “extremely thin sheet of metal foil with a carrier (not shown).” The extremely thin sheet of metal foil with the carrier has a triple layer structure. That is to say, the extremely thin sheet of metal foil with the carrier includes: the carrier; a peelable layer provided on the surface of the carrier; and an extremely thin sheet of metal foil provided on the surface of the peelable layer. The extremely thin sheet of metal foil is too thin to be handled easily by itself and is naturally thinner than the carrier. The carrier is a sheet of metal foil (such as a sheet of copper foil) that plays the role of protecting and supporting the extremely thin sheet of metal foil. The extremely thin sheet of metal foil with the carrier is relatively thick and thick enough to handle easily. The respective thicknesses of the extremely thin sheet of metal foil and the carrier are not limited to any particular value. For example, the extremely thin sheet of metal foil may have a thickness equal to or greater than 1 μm and equal to or less than 10 μm. The carrier may have a thickness equal to or greater than 18 μm and equal to or less than 35 μm. The extremely thin sheet of metal foil may be peeled off as needed from the peelable layer.

When the extremely thin sheet of metal foil with the carrier is used, the sheet of metal foil 3 with resin may be manufactured in the following manner. Specifically, the resin composition is applied onto the surface of the extremely thin sheet of metal foil of the extremely thin sheet of metal foil with the carrier and heated to form a resin layer 31. Thereafter, the carrier is peeled off from the extremely thin sheet of metal foil. The extremely thin sheet of metal foil is bonded as a sheet of metal foil 32 to the surface of the resin layer 31. The peelable layer is preferably peeled off along with the carrier and should not be left on the surface of the extremely thin sheet of metal foil. Nevertheless, even if any part of the peelable layer remains on the surface of the extremely thin sheet of metal foil, the remaining part of the peelable layer is easily removable. The extremely thin sheet of metal foil bonded to the surface of the resin layer 31 may be used as a seed layer in a modified semi-additive process (MSAP). The wiring 53 may be formed by subjecting the seed layer to an electrolytic plating process.

### <Metal-Clad Laminate>

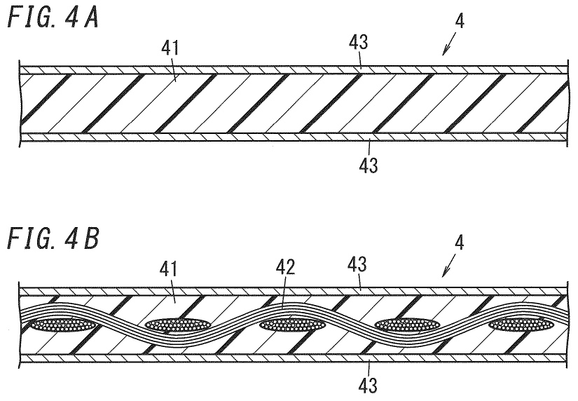

FIGS. 4A and 4B illustrate a metal-clad laminate 4 according to this embodiment. The metal-clad laminate 4 includes an insulating layer 41 and at least one metal layer 43. In the metal-clad laminate 4 shown in FIG. 4A, the insulating layer 41 includes a cured product of the resin composition. In the metal-clad laminate 4 shown in FIG. 4B, the insulating layer 41 includes a cured product of at least one prepreg. The cured product of the prepreg includes a fibrous base member 42. As can be seen, the metal-clad laminate 4 shown in FIG. 4B may be manufactured with the prepreg used as its material. The insulating layer 41 is a layer which has electrical insulation properties and is in an insoluble and non-meltable state. The metal layer 43 is bonded to the insulating layer 41.

The metal layer 43 is not limited to any particular one as long as the metal layer 43 is a layer containing a metal. Specifically, the metal layer 43 may be a sheet of copper foil. The metal layer 43 preferably has a thickness equal to or greater than 18 μm and equal to or less than 210 μm. The metal layer 43 preferably has a ten-point average roughness Rzjis equal to or greater than 5.0 μm. This may further increase the degree of adhesion between the insulating layer 41 and the metal layer 43.

A method for manufacturing the metal-clad laminate 4 shown in FIG. 4B includes the step of stacking a metal layer 43 such as a sheet of metal foil on one or both sides of a laminate made up of either one prepreg 2 or two or more prepregs 2 and heating and pressing the assembly, for example. Preferably, before the metal layer 43 is stacked on the laminate, the surface of the metal layer 43 (at least its surface to be laid on the laminate) is treated with a coupling agent. Treating the surface of the metal layer 43 with the coupling agent in this manner causes the coupling agent to bond the organic material in the prepreg 2 to the metal layer 43, thus further increasing the degree of adhesion between the insulating layer 41 and the metal layer 43. As the coupling agent, a silane coupling agent may be used, for example. The condition for heating and pressing is not limited to any particular one. FIG. 4B illustrates a metal-clad laminate 4 formed through the step of stacking a metal layer 43 on each of the two sides of the laminate consisting of one prepreg 2 and then heating and pressing the assembly.

### <Printed Wiring Board>

FIGS. 5A and 5B illustrate a printed wiring board 5 according to this embodiment. The printed wiring board 5 includes at least one insulating layer 51 and at least one conductor layer 530.

In the printed wiring board 5 shown in FIG. 5A, the insulating layer 51 includes a cured product of the resin composition. In the printed wiring board 5 shown in FIG. 5B, the insulating layer 51 includes a cured product of at least one prepreg. The cured product of the prepreg includes a fibrous base member 52. The insulating layer 51 is a layer having electrical insulation properties and exhibiting an insoluble and non-meltable state.

The conductor layer 530 is bonded to the insulating layer 51. As used herein, the “conductor layer” refers to a layer with electrical conductivity such as a signal layer, a power supply layer, or a ground layer. The conductor layer 530 includes the wiring 53.

Also, as used herein, the printed wiring board 5 is a term referring to not only a printed wiring board including at most two conductor layers 530 but also a multilevel printed wiring board including three or more conductor layers 530. Note that a printed wiring board including two conductor layers 530 and one insulating layer 51 is shown in each of FIGS. 5A and 5B.

The printed wiring board 5 may be manufactured by, for example, a subtractive process using the metal-clad laminate 4 as its material. Alternatively, the printed wiring board 5 may also be formed to have a multilevel structure by a build-up process using the film 1 with resin and the sheet of metal foil 3 with resin.

The printed wiring board 5 may have one or more pieces of through hole plating 54. The through hole plating 54 may be formed by, for example, drilling a hole through the insulating layer 51, performing a desmear process on the hole, and then plating the inner wall of the hole with copper, for instance. The desmear process may be performed by, for example, permanganate method. Although not shown, the printed wiring board 5 may have one or more blind via holes. Note that the hole may be a through hole or a non-through hole, whichever is appropriate.

### EXAMPLES

The present disclosure will be described specifically by way of specific examples. Note that the present disclosure is not limited to the following examples.

### [Materials]

Following materials were used as materials for resin compositions representing examples of the present disclosure and comparative examples.

### <Epoxy Resin (A)>

Epoxy resin 1: trisphenol-methane epoxy resin, product number: EPPN502H M60 manufactured by Nippon Kayaku Co., Ltd., having an epoxy equivalent of 170 g/eq and a softening point of 60-72° C.; and
Epoxy resin 2: trisphenol-methane epoxy resin, product number: HP-7250 M80 manufactured by DIC Corporation, having an epoxy equivalent of 164 g/eq, in semi-solid phase.

### <Inorganic Filler (B)>

### <<Inorganic Filler (B1)>>.

Alumina filler 1: product number: AZ10-20 manufactured by NIPPON STEEL Chemical & Material Co., Ltd.;
Alumina filler 2: product number: AZ10-75 manufactured by NIPPON STEEL Chemical & Material Co., Ltd.;
Magnesium carbonate filler: product number: MAGTHERMO MS-PS (synthetic magnesite) manufactured by Konoshima Chemical Co., Ltd.;
Magnesium oxide filler: product number: RF-10CS manufactured by Ube Material Industries, Ltd.; and
Aluminum nitride filler: product number: HF-10c manufactured by Tokuyama Corporation.

### <<Inorganic Filler (B2)>>

Alumina filler 3: product number: AO-502 manufactured by Admatechs.

### <Other Inorganic Fillers>

Molybdic acid compound filler: product number: KG-501 manufactured by Huber; and
Silica filler: product number: MEK-EC-2130Y manufactured by Nissan Chemical Corporation.

### <Heavy Metal Deactivator (C)>

Heavy metal deactivator: hydrazide-based nitrogen compound, product number: ADEKA STAB CDA-10 manufactured by ADEKA Corporation.

### <Ion Scavenger (D)>

Ion scavenger 1: hydrotalcite-based ion scavenger, product number: IXEPLAS-A3 manufactured by Toagosei Co., Ltd.:
Ion scavenger 2: hydrotalcite-based ion scavenger, product number: IXEPLAS-A1 manufactured by Toagosei Co., Ltd.; and
Ion scavenger 3: bismuth oxide-based ion scavenger, product number: IXE-500, manufactured by Toagosei Co., Ltd.

### <Curing Agent (E)>

Curing agent: biphenyl-aralkyl phenolic resin, product number: MEHC-7403H manufactured by Meiwa Plastic Industries, Ltd., having a hydroxyl group equivalent of 132 g/eq.

### <Curing Catalyst (F)>

Curing catalyst: 2-ethyl-4-methylimidazole, product number: 2E4MZ manufactured by Shikoku Chemicals Corporation.

### <Flame Retardant (G)>

Flame retardant: phosphazene-based flame retardant, product number: Rabitle FP-100 manufactured by Mitsui Fine Chemicals, Inc.

### <Other Components>

Coupling agent: epoxy-group-containing silane coupling agent, product number: KBM-4803, manufactured by Shin-Etsu Silicones; and
Dispersant: wetting dispersant, product number: BYK-W903 manufactured by BYK-Chemie gmbh.

In the following Table 1, the “content (phr) of component (C)” means the parts by mass of the heavy metal deactivator (C) with respect to 100 parts by mass of the resin components (i.e., the combination of the epoxy resin (A) and the curing agent (E)).

### [Preparation of Varnish]

These materials were compounded to have any of the compositions shown in Table 1. The compound was dissolved or dispersed in methyl ethyl ketone as a solvent so that the solid content thereof would be 80-95% by mass. Then, the mixture was stirred up with a planetary mixer. In this manner, varnishes respectively containing the resin compositions according to the examples and comparative examples were prepared.

[Manufacturing of Film with Resin]

The varnish was applied onto a PET film as a supporting film and then heated to about 150° C. for 4 to 5 minutes to turn the resin composition into a semi-cured product. In this manner, a film with resin was manufactured. The thickness of the resin layer was adjusted to 100 μm.

### [Manufacturing of Copper-Clad Laminate]

Eight films with resin, each of which was manufactured as described above, were stacked one on top of another with the supporting film peeled off, and the stack of these films was sandwiched between the roughened surfaces of two sheets of copper foil (with a thickness of 35 μm) and the assembly was heated and pressed at a temperature of 200° C. under a pressure of 2.94 MPa (=30 kgf/cm²) for 60 minutes. In this manner, a copper-clad laminate (CCL), of which the insulating layer had an overall thickness of 800 μm, was manufactured.

### [Evaluation Tests]

### (Thermal Conductivity)

The thermal conductivity of the insulating layer of the copper-clad laminate thus manufactured was measured by the laser flash method defined by JIS R 1611. The measured values of the thermal conductivity are shown in the following Table 1.

The samples may be graded as follows by thermal conductivity:
Grade A (excellent): if the thermal conductivity of the sample was equal to or greater than 4.5 W/m·K:
Grade B (good): if the thermal conductivity of the sample was equal to or greater than 4 W/m. K and less than 4.5 W/m. K: or
Grade C (not good): if the thermal conductivity of the sample was less than 4 W/m. K.

### (Insulation Reliability)

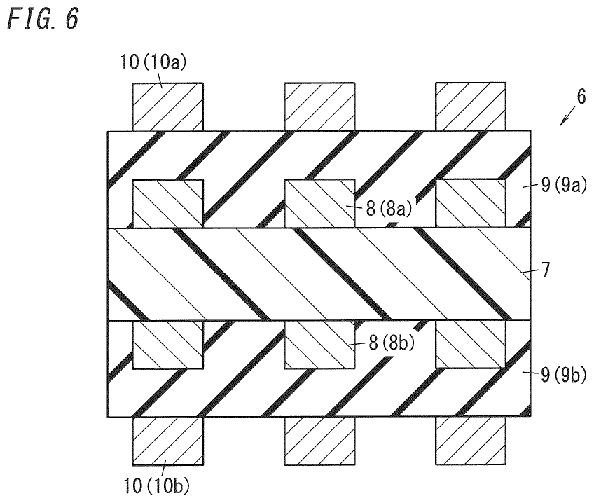

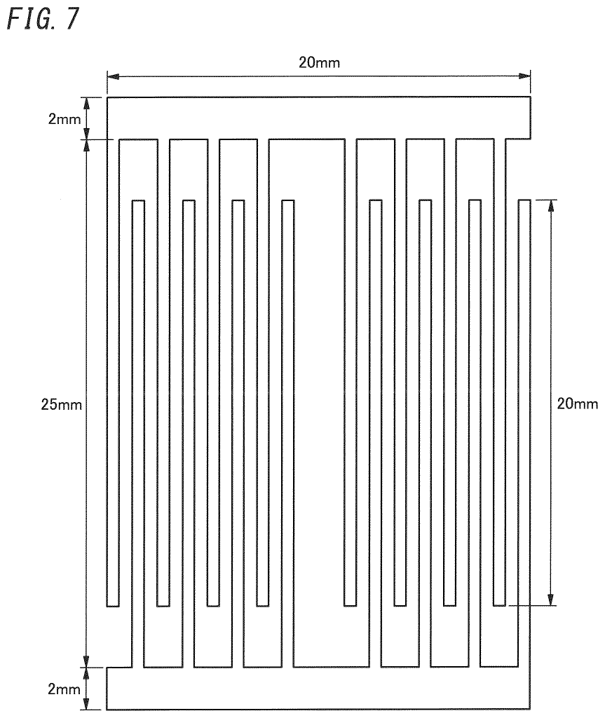

A board for evaluating long-term insulation properties for use to evaluate the insulation reliability of the insulating layer was obtained in the following manner. First, a double-sided copper-clad laminate (including a core member 7 with a thickness of 400 μm and inner sheets of copper foil 8 (8a and 8b) with a thickness of 105 μm and dimensions of 515 mm×340 mm) was subjected to an etching process to form a comb-shaped pattern and prepare a printed wiring board under test. Next, a resin film (having a thickness of 150 μm and dimensions of 510 mm×340 mm) which had been formed using the varnish of the resin composition that had been prepared as described above was stacked on each of the two surfaces of the printed wiring board. Subsequently, a sheet of copper foil as an outermost layer 10 (10a, 10b) having a thickness of 105 μm and dimensions of 550 mm×700 mm was further stacked on each of the outermost layers of the assembly. Then, the structure thus formed was thermally pressed under the condition including 200° C., 3 MPa, and 60 minutes to cause the resin films to cure and thereby form an insulating layer 9 (9a, 9b). In this manner, a laminate was prepared. Then, the sheet of copper foil 10 as the outermost layer of the laminate that had been thermally pressed was subjected to an etching process, thereby forming the comb pattern shown in FIG. 7. As a result, a board 6 for evaluating long-term insulation properties having a cross section such as the one shown in FIG. 6 and including an insulating layer 9 in which the distance between a sheet of coper foil 8 as an inner layer and a sheet of copper foil 10 as the outermost layer was 100 μm was obtained.

Next, the board for evaluation thus obtained was placed in an environment having a temperature of 85° C. and a humidity of 85%. A voltage of 900 V was applied to the sheet of copper foil as the outermost layer and the sheet of copper foil as the inner layer to measure the resistance value of a film member that was used as the insulating layer 9. Then, the amount of time (hereinafter also referred to as an “amount of time X”) it took for the resistance value thus measured to reach 1×10⁷Ω or less was monitored to carry out the insulation property evaluation until 2,000 hours passed. The measurements were taken five times. The measured value (as an average value) of the amount of time X (in the unit of Hr) is shown in the following Table 1:

The samples may be graded in terms of their insulation reliability as follows:
Grade A (excellent): if the amount of time X was equal to or longer than 700 hours;
Grade B (good): if the amount of time X was equal to or longer than 200 hours and shorter than 700 hours; or
Grade C (not good): if the amount of time X was shorter than 200 hours.

TABLE 1

| Content | | | | | | | | |
|---|---|---|---|---|---|---|---|---|
| (parts by mass) | | | Ex. 1 | Ex. 2 | Ex. 3 | Ex. 4 | Ex. 5 | Ex. 6 |
| Component (A) | | Epoxy resin 1 | 20.0 | 20.0 | 20.0 | 20.0 | 20.0 | 20.0 |
| | | Epoxy resin 2 | 40.0 | 40.0 | 40.0 | 40.0 | 40.0 | 40.0 |
| Component | (B1) | Alumina filler 1 | 945.0 | 960.0 | 1020.0 | 1020.0 | 1005.0 | 1035.0 |
| (B) | | Alumina filler 2 | | | | | | |
| | | Magnesium carbonate filler | | | | | | |
| | | Magnesium oxide filler | | | | | | |
| | | Aluminum nitride filler | | | | | | |
| | (B2) | Alumina filler 3 | 630.0 | 640.0 | 680.0 | 680.0 | 670.0 | 690.0 |

| | | | | | | | |
|---|---|---|---|---|---|---|---|
| Other inorganic | Molybdic acid compound filler | 65.0 | 66.0 | 70.0 | 70.0 | 70.0 | 70.0 |
| Fillers | Silica filler | 4.0 | 4.0 | 4.0 | 4.0 | 4.0 | 4.0 |
| Component (C) | Heavy metal deactivator | 1.0 | | | | | 1.0 |
| Component (D) | Ion scavenger 1 | | 4.5 | 20.0 | | | |
| | Ion scavenger 2 | | | | 20.0 | | 20.0 |
| | Ion scavenger 3 | | | | | 20.0 | |
| Component (E) | Curing agent | 40.0 | 40.0 | 40.0 | 40.0 | 40.0 | 40.0 |
| Component (F) | Caring catalyst | 0.5 | 0.5 | 0.5 | 0.5 | 0.5 | 0.5 |
| Component (G) | Flame retardant | 10.0 | 10.0 | 10.0 | 10.0 | 10.0 | 10.0 |
| Component (H) | Coupling agent | 16.4 | 16.7 | 17.7 | 17.7 | 17.5 | 18.0 |
| | Dispersant | 11.5 | 11.7 | 12.4 | 12.4 | 12.2 | 12.6 |

| | | | | | | | |
|---|---|---|---|---|---|---|---|
| Content | Component (C) (phr) | 1.0 | 0.0 | 0.0 | 0.0 | 0.0 | 1.0 |
| | Component (D) in mass % to composition | 0 | 0.25 | 1.0 | 1.0 | 1.0 | 1.0 |
| | Component (B) in mass % to composition | 88.3 | 88.2 | 87.9 | 87.9 | 87.7 | 88.0 |
| | (B1)/(B2) ratio by volume | 60/40 | 60/40 | 60/40 | 60/40 | 60/40 | 60/40 |
| Evaluation | Thermal conductivity (W/m · K) | 4 | 4 | 4 | 4 | 4 | 4 |
| | Insulation reliability (time X (Hr)) | 678 | 570 | 1048 | 1043 | 806 | 1233 |

| Content | | | | | | Cmp. | Cmp. | Cmp. |
|---|---|---|---|---|---|---|---|---|
| (parts by mass) | | | Ex. 7 | Ex. 8 | Ex. 9 | Ex. 1 | Ex. 2 | Ex. 3 |
| Component (A) | | Epoxy resin 1 | 20.0 | 20.0 | 20.0 | 20.0 | 20.0 | 20.0 |
| | | Epoxy resin 2 | 40.0 | 40.0 | 40.0 | 40.0 | 40.0 | 40.0 |
| Component | (B1) | Alumina filler 1 | 1230.0 | 793.0 | | 930.0 | | |
| (B) | | Alumina filler 2 | | | | | 1020.0 | |
| | | Magnesium carbonate Eller | | | | | | 490.0 |
| | | Magnesium oxide filler | | 264.0 | | | | |
| | | Aluminum nitride filler | | | 980.0 | | | |
| | (B2) | Alumina filler 3 | 820.0 | 705.0 | 575.0 | 620.0 | 680.0 | 520.0 |

| | | | | | | | |
|---|---|---|---|---|---|---|---|
| Other inorganic | Molybdic acid compound filler | 82.0 | 73.0 | 71.0 | 68.0 | 70.0 | 50.0 |
| Fillers | Silica filler | 4.0 | 4.0 | 4.0 | 4.0 | 4.0 | 4.0 |
| Component (C) | Heavy metal deactivator | 1.0 | 1.0 | 1.0 | | | |
| Component (D) | Ion scavenger 1 | | | | | 20.0 | |
| | Ion scavenger 2 | 23.0 | 20.0 | 18.0 | | | |
| | Ion scavenger 3 | | | | | | |
| Component (E) | Curing agent | 40.0 | 40.0 | 40.0 | 40.0 | 40.0 | 40.0 |
| Component (F) | Caring catalyst | 0.5 | 0.5 | 0.5 | 0.5 | 0.5 | 0.5 |
| Component (G) | Flame retardant | 10.0 | 10.0 | 10.0 | 10.0 | 10.0 | 10.0 |
| Component (H) | Coupling agent | 21.3 | 18.6 | 16.3 | 16.1 | 17.7 | 10.6 |
| | Dispersant | 14.9 | 13.0 | 11.4 | 11.3 | 12.4 | 7.4 |

| | | | | | | | |
|---|---|---|---|---|---|---|---|
| Content | Component (C) (phr) | 1.0 | 1.0 | 1.0 | 0.0 | 0.0 | 0.0 |
| | Component (D) in mass % to composition | 1.0 | 1.0 | 1.0 | 0.0 | 1.0 | 0.0 |
| | Component (B) in mass % to composition | 88.9 | 88.0 | 87.0 | 88.3 | 87.9 | 84.7 |
| | (B1)/(B2) ratio by volume | 60/40 | 60/40 | 67/33 | 60/40 | 60/40 | 55/45 |
| Evaluation | Thermal conductivity (W/m · K) | 4.5 | 4.5 | 5.5 | 4 | 4.5 | 2.7 |
| | Insulation reliability (time X (Hr)) | 373 | 705 | 594 | 184 | 183 | >2000 |

Also, from the inorganic filler (B) that was used to prepare the resin composition, impurity ions were extracted as ultrapure water (with an electrical conductivity of 0.1 μS/cm at 25° C.) by the method described in the foregoing description. Then, the electrical conductivity and impurity ion concentrations of the extracted water thus obtained were measured. The results of measurement are shown, along with D50 and D99 values of the inorganic filler (B), in the following Table 2. In Table 2, “50<D99<80” indicates that D99 of alumina filler 2 was greater than 50 μm and less than 80 μm.

TABLE 2

| | | | Properties of extracted water | | | | | | |
|---|---|---|---|---|---|---|---|---|---|
| | Particle size | | Electrical | | | | | | |
| | D50 | D99 | Conductivity | Concentration of ion impurity | | | | | |
| | (μm) | (μm) | (μS/cm) | Cl⁻ | NO₂⁻ | NO₃⁻ | PO₄³⁻ | SO₄²⁻ | NH₄⁺ |
| Alumina filler 1 | 8-10 | <40 | 10 | <2 | <2 | <2 | <2 | <2 | <2 |
| Alumina filler 2 | 10-15 | 50 < D99 < 80 | 8 | <2 | <2 | <2 | <2 | <2 | <2 |
| Magnesium carbonate filler | 10-13 | <50 | 60 | 2 | <2 | <2 | <2 | 6 | 16 |
| Magnesium oxide filler | 5-10 | <50 | 407 | 3 | <2 | <2 | <2 | 8 | <2 |
| Aluminum nitride filler | 5-10 | <40 | 2030 | <2 | 23 | 20 | <2 | 44 | 217984 |
| Alumina filler 3 | 0.2-0.3 | <5 | 6 | <2 | <2 | <2 | <2 | <2 | <2 |

### (Recapitulation)

As can be seen from the foregoing description of embodiments and their variations, a resin composition according to a first aspect of the present disclosure contains: an epoxy resin (A); an inorganic filler (B) having a thermal conductivity equal to or greater than 10 W/m·K; and at least one selected from the group consisting of a heavy metal deactivator (C) and an ion scavenger (D). The inorganic filler (B) has a volume-based cumulative 99% particle size equal to or less than 50 μm as measured by a laser diffraction particle size distribution analysis method. The content of the inorganic filler (B) is equal to or greater than 84% by mass and equal to or less than 97% by mass with respect to the resin composition.

The first aspect allows for providing a resin composition, from which a cured product exhibiting not only high thermal conductivity but also excellent insulation reliability as well may be formed.

In a second aspect of the present disclosure, which may be implemented in conjunction with the first aspect, the inorganic filler (B) includes at least one filler selected from the group consisting of an aluminum oxide filler, a magnesium oxide filler, an anhydrous magnesium carbonate filler, and an aluminum nitride filler.

The second aspect may further improve the thermal conductivity of the cured product of the resin composition by using, as the inorganic filler (B), a material which not only has high thermal conductivity but also is easily available.

In a third aspect of the present disclosure, which may be implemented in conjunction with the first or second aspect, extracted water, obtained by making a mixture including 15 g of the inorganic filler (B) and 7.5 g of ultrapure water and heating the mixture at 125° C. for 20 hours, has an electrical conductivity equal to or less than 500 μS/cm, and respective concentrations of Cl⁻, SO₄²⁻, PO₄³⁻, NO₂⁻, NO₃⁻, and NH₄⁺ in the extracted water are equal to or lower than 20 ppm.

The third aspect may further improve the insulation reliability of the cured product of the resin composition by using, as the inorganic filler (B), a filler having impurity ions at such a low concentration.

In a fourth aspect of the present disclosure, which may be implemented in conjunction with any one of the first to third aspects, the inorganic filler (B) has at least two peaks in a volume-based particle size distribution measured by the laser diffraction particle size distribution analysis method. The at least two peaks include a first peak and a second peak. The first peak is located at a point greater than 1 μm and equal to or less than 30 μm. The second peak is located at a point equal to or greater than 0.1 μm and equal to or less than 1 μm.

The fourth aspect allows the resin composition to include the inorganic filler (B) at an even higher fillability, thus enabling the thermal conductivity of the cured product of the resin composition to be further improved.

In a fifth aspect of the present disclosure, which may be implemented in conjunction with the fourth aspect, the inorganic filler (B) includes at least two inorganic fillers including a first inorganic filler (B1) marking the first peak and a second inorganic filler (B2) marking the second peak.

According to the fifth aspect, the inorganic filler (B) includes at least two inorganic fillers, of which the peaks in a particle size distribution are located at different points, thus further increasing the fillability of the inorganic filler (B) in the resin composition and eventually further improving the thermal conductivity of the cured product of the resin composition.

In a sixth aspect of the present disclosure, which may be implemented in conjunction with the fifth aspect, the first inorganic filler (B1) includes at least one filler selected from the group consisting of an aluminum oxide filler, a magnesium oxide filler, an anhydrous magnesium carbonate filler, and an aluminum nitride filler.

According to the sixth aspect, one of these fillers with relatively high thermal conductivity is used as the first inorganic filler (B1) having the larger particle size among the at least two types of inorganic filler (B), thus enabling the thermal conductivity of the cured product of the resin composition to be further improved.

In a seventh aspect of the present disclosure, which may be implemented in conjunction with the fifth or sixth aspect, the second inorganic filler (B2) has either a spherical shape or a round shape.

According to the seventh aspect, the at least two types of inorganic filler (B) include a filler with such a shape as the second inorganic filler (B2) having the smaller particle size, thus allowing the resin composition to include the inorganic filler (B) at an even higher fillability and thereby enabling the thermal conductivity of the cured product to be further improved.

In an eighth aspect of the present disclosure, which may be implemented in conjunction with any one of the fifth to seventh aspects, a ratio by volume of the first inorganic filler (B1) to the second inorganic filler (B2) is equal to or greater than 40/60 and equal to or less than 70/30.

According to the eighth aspect, the (B1)/(B2) ratio by volume of the inorganic filler (B) is set to fall within this range, thus allowing the resin composition to include the inorganic filler (B) at an even higher fillability and thereby enabling the thermal conductivity of the cured product of the resin composition to be further improved.

In a ninth aspect of the present disclosure, which may be implemented in conjunction with any one of the first to eighth aspects, the heavy metal deactivator (C) includes at least one selected from the group consisting of hydrazide-based nitrogen compounds, triazine-based nitrogen compounds, and triazole-based nitrogen compounds.

According to the ninth aspect, one of these compounds is used as the heavy metal deactivator (C), thus enabling the cured product of the resin composition to have further improved insulation reliability.

In a tenth aspect of the present disclosure, which may be implemented in conjunction with any one of the first to ninth aspects, the ion scavenger (D) includes at least one selected from the group consisting of hydrotalcite-based ion scavengers, bismuth oxide-based ion scavengers, antimony oxide-based ion scavengers, titanium phosphate-based ion scavengers, and zirconium phosphate-based ion scavengers.

According to the tenth aspect, one of these ion scavengers is used as the ion scavenger (D), thus enabling the cured product of the resin composition to have further improved insulation reliability.

A film (1) with resin according to an eleventh aspect of the present disclosure includes: a resin layer (11) including either the resin composition according to any one of the first to tenth aspects or a semi-cured product of the resin composition; and a supporting film (12).

The eleventh aspect allows for providing a film (1) with resin including a resin layer (11), which may be patterned into an insulating layer exhibiting not only high thermal conductivity but also excellent insulation reliability as well.

A prepreg (2) according to a twelfth aspect of the present disclosure includes: a resin layer (21) including either the resin composition according to any one of the first to tenth aspects or a semi-cured product of the resin composition; and a fibrous base member (22).

The twelfth aspect allows for providing a prepreg (2) including a resin layer (11), which may be patterned into an insulating layer exhibiting not only high thermal conductivity but also excellent insulation reliability as well.

A sheet of metal foil (3) with resin according to a thirteenth aspect of the present disclosure includes: a resin layer (31) including either the resin composition according to any one of the first to tenth aspects or a semi-cured product of the resin composition; and a sheet of metal foil (32).

The thirteenth aspect allows for providing a sheet of metal foil (3) with resin including a resin layer (31), which may be patterned into an insulating layer exhibiting not only high thermal conductivity but also excellent insulation reliability as well.

A metal-clad laminate (4) according to a fourteenth aspect of the present disclosure includes: an insulating layer (41) including a cured product of the resin composition according to any one of the first to tenth aspects; and a metal layer (43).

The fourteenth aspect allows for providing a metal-clad laminate (4) including an insulating layer (41) exhibiting not only high thermal conductivity but also excellent insulation reliability as well.

A printed wiring board (5) according to a fifteenth aspect of the present disclosure includes: an insulating layer (51) including a cured product of the resin composition according to any one of the first to tenth aspects; and wiring (53).

The fifteenth aspect allows for providing a printed wiring board (5) including an insulating layer (51) exhibiting not only high thermal conductivity but also excellent insulation reliability as well.

A metal-clad laminate (4) according to a sixteenth aspect of the present disclosure includes: an insulating layer (41) including a cured product of the prepreg (2) according to the twelfth aspect; and a metal layer (43).

The sixteenth aspect allows for providing a metal-clad laminate (4) including an insulating layer (41) exhibiting not only high thermal conductivity but also excellent insulation reliability as well.

A printed wiring board (5) according to a seventeenth aspect of the present disclosure includes: an insulating layer (51) including a cured product of the prepreg (2) according to the twelfth aspect; and wiring (53).

The seventeenth aspect allows for providing a printed wiring board (5) including an insulating layer (51) exhibiting not only high thermal conductivity but also excellent insulation reliability as well.

### REFERENCE SIGNS LIST

1 Film with Resin
11 Resin Layer
12 Supporting Film
2 Prepreg
21 Resin Layer
22 Fibrous Base Member
3 Sheet of Metal Foil with Resin
31 Resin Layer
32 Sheet of Metal Foil
4 Metal-Clad Laminate
41 Insulating Layer
43 Metal Layer
5 Printed Wiring Board
51 Insulating Layer
53 Wiring

1. A resin composition containing:
an epoxy resin (A);
an inorganic filler (B) having a thermal conductivity equal to or greater than 10 W/m·K; and
at least one selected from the group consisting of a heavy metal deactivator (C) and an ion scavenger (D),
the inorganic filler (B) having a volume-based cumulative 99% particle size equal to or less than 50 μm as measured by a laser diffraction particle size distribution analysis method, and
content of the inorganic filler (B) being equal to or greater than 84% by mass and equal to or less than 97% by mass with respect to the resin composition.

2. The resin composition of claim 1, wherein
the inorganic filler (B) includes at least one filler selected from the group consisting of an aluminum oxide filler, a magnesium oxide filler, an anhydrous magnesium carbonate filler, and an aluminum nitride filler.

3. The resin composition of claim 1, wherein
extracted water, obtained by making a mixture including 15 g of the inorganic filler (B) and 7.5 g of ultrapure water and heating the mixture at 125° C. for 20 hours, has an electrical conductivity equal to or less than 500 μS/cm, and
respective concentrations of Cl⁻, SO₄²⁻, PO₄³⁻, NO₂⁻, NO₃⁻, and NH₄⁺ in the extracted water are equal to or lower than 20 ppm.

4. The resin composition of claim 1, wherein
the inorganic filler (B) has at least two peaks in a volume-based particle size distribution measured by a laser diffraction particle size distribution analysis method, the at least two peaks including a first peak and a second peak,
the first peak is located at a point greater than 1 μm and equal to or less than 30 μm, and
the second peak is located at a point equal to or greater than 0.1 μm and equal to or less than 1 μm.

5. The resin composition of claim 4, wherein
the inorganic filler (B) includes at least two inorganic fillers including a first inorganic filler (B1) marking the first peak and a second inorganic filler (B2) marking the second peak.

6. The resin composition of claim 5, wherein
the first inorganic filler (B1) includes at least one filler selected from the group consisting of an aluminum oxide filler, a magnesium oxide filler, an anhydrous magnesium carbonate filler, and an aluminum nitride filler.

7. The resin composition of claim 5, wherein
the second inorganic filler (B2) has either a spherical shape or a round shape.

8. The resin composition of claim 5, wherein
a ratio by volume of the first inorganic filler (B1) to the second inorganic filler (B2) is equal to or greater than 40/60 and equal to or less than 70/30.

9. The resin composition of claim 1, wherein
the heavy metal deactivator (C) includes at least one selected from the group consisting of hydrazide-based nitrogen compounds, triazine-based nitrogen compounds, and triazole-based nitrogen compounds.

10. The resin composition of claim 1, wherein
the ion scavenger (D) includes at least one selected from the group consisting of hydrotalcite-based ion scavengers, bismuth oxide-based ion scavengers, antimony oxide-based ion scavengers, titanium phosphate-based ion scavengers, and zirconium phosphate-based ion scavengers.

11. A film with resin, comprising:
a resin layer including either the resin composition of claim 1 or a semi-cured product of the resin composition; and
a supporting film.

12. A prepreg comprising:
a resin layer including either the resin composition of claim 1 or a semi-cured product of the resin composition; and
a fibrous base member.

13. A sheet of metal foil with resin, comprising:
a resin layer including either the resin composition of claim 1 or a semi-cured product of the resin composition; and
a sheet of metal foil.

14. A metal-clad laminate comprising:
an insulating layer including a cured product of the resin composition of claim 1; and
a metal layer.

15. A printed wiring board comprising:
an insulating layer including a cured product of the resin composition of claim 1; and
wiring.

16. A metal-clad laminate comprising:
an insulating layer including a cured product of the prepreg of claim 12; and
a metal layer.

17. A printed wiring board comprising:
an insulating layer including a cured product of the prepreg of claim 12; and
wiring.
